(19) United States
(12) Patent Application Publication
(10) Pub. No.: US 2020/0227273 A1
(43) Pub. Date: Jul. 16, 2020

(54) HARD MASK AND SEMICONDUCTOR DEVICE MANUFACTURING METHOD

(71) Applicant: TOKYO ELECTRON LIMITED, Tokyo (JP)

(72) Inventors: Hiroyuki TOSHIMA, Nirasaki City (JP); Shinji FURUKAWA, Tokyo (JP); Shota ISHIBASHI, Nirasaki City (JP)

(21) Appl. No.: 16/743,466

(22) Filed: Jan. 15, 2020

(30) Foreign Application Priority Data
Jan. 16, 2019 (JP) 2019-005444

(51) Int. Cl. H01L 21/311; H01L 21/3065; H01L 21/027; H01L 21/203; H01L 21/285; C23C 14/14; C23C 14/22

(52) U.S. Cl. CPC H01L 21/31144; H01L 21/3065; H01L 21/027; C23C 14/22; H01L 21/28556; C23C 14/14; H01L 21/203

(57) ABSTRACT

There is provided a hard mask formed on a substrate for manufacturing a semiconductor device, the hard mask including a film made of a compound which is composed of Ru and an element selected from Ti, Zr, Hf, V, Nb, Ta, Mo, W, and Si.

### CROSS-REFERENCE TO RELATED APPLICATION

This application is based upon and claims the benefit of priority from Japanese Patent Application No. 2019-005444, filed on Jan. 16, 2019, the entire contents of which are incorporated herein by reference.

### TECHNICAL FIELD

The present disclosure relates to a hard mask and a semiconductor device manufacturing method.

### BACKGROUND

In a semiconductor device manufacturing process, etching is performed using an etching gas in order to form wires in an etching-target film formed on a semiconductor wafer (hereinafter, referred to as a “wafer”), which is a substrate. There may be a case Where a hard mask is used in such an etching.

Patent Document 1 discloses a technology which uses a hard mask made of a material containing at least one type of metal selected from a metal group including ruthenium, tantalum, titanium and the like in order to form a pattern on a light-shielding film formed on a substrate constituting a photomask. Patent Document 2 discloses a technology which forms a multilayer reflective film as a silicon film and an alloy film made of ruthenium and titanium, on a substrate constituting a photomask upwards in the named order in order to manufacture a reflective mask (the photomask) for EUV lithography. The alloy film constitutes a protective film for preventing the production of silicon oxide during cleaning and etching for manufacturing the photomask.

### PRIOR ART DOCUMENT

### Patent Document

Patent Document 1: Japanese Laid-Open Patent Publication No. 2018-010080

Patent Document 2: Publication of WO2015/037564

### SUMMARY

According to an embodiment of the present disclosure, there is provided a hard mask formed on a substrate for manufacturing a semiconductor device, the hard mask including: a film made of a compound which is composed of Ru and an element selected from Ti, Zr, Hf, V, Nb, Ta, Mo, W, and Si.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1A is view illustrating a semiconductor device manufacturing process according to an embodiment of the present disclosure.

FIG. 1B is view illustrating a semiconductor device manufacturing process according to an embodiment of the present disclosure.

FIG. IC is view illustrating a semiconductor device manufacturing process according to an embodiment of the present disclosure.

FIG. 2A is view illustrating a semiconductor device manufacturing process according to an embodiment of the present disclosure.

FIG. 2B is view illustrating a semiconductor device manufacturing process according to an embodiment of the present disclosure.

FIG. 2C is view illustrating a semiconductor device manufacturing process according to an embodiment of the present disclosure.

FIG. 3 is view illustrating a semiconductor device manufacturing process according to an embodiment of the present disclosure.

FIG. 4 is a view schematically illustrating a configuration of a system which implements the semiconductor device manufacturing process.

FIG. 5 is a view schematically illustrating a configuration of an exposure apparatus included in the system.

FIG. 6 is a vertical cross-sectional view of a film forming apparatus included in the system.

FIG. 7A is view illustrating a semiconductor device manufacturing process of another embodiment of the present disclosure.

FIG. 7B is view illustrating a semiconductor device manufacturing process of another embodiment of the present disclosure.

FIG. 8 is a graph representing a result of an evaluation test.

FIG. 9 is a graph representing a result of an evaluation test.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

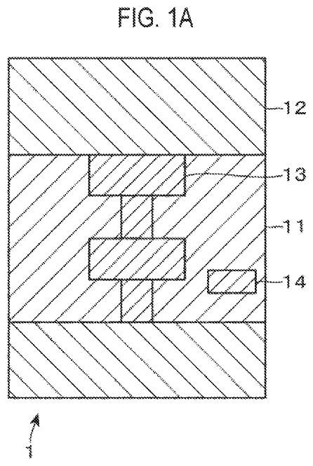

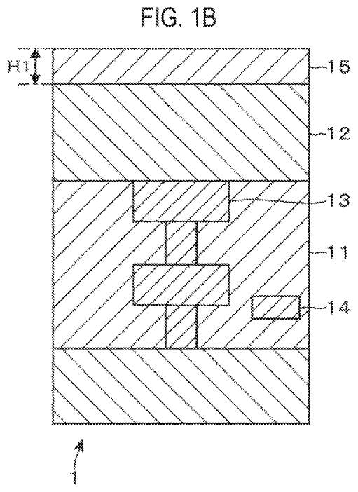

A semiconductor device manufacturing process according to an embodiment of the present disclosure will be described with reference to FIGS. 1A to 1C, FIGS. 2A to 2C, and FIG. 3. These figures are vertical cross-sectional views of a wafer 1, which is a substrate for manufacturing a semiconductor device. As illustrated in FIG. 1A, a lower layer film 11 and an upper layer film 12 are formed on a front surface of the wafer 1 upwards in the named order. A wire 13 constituting a semiconductor device has been formed in the lower layer film 11. The lower layer film 11 is provided with an alignment mark 14 for aligning the wafer 1 (which will be described later). In this example, the upper layer film 12 is made of SiO₂ (silicon oxide).

First, a mask film 15 is formed on the upper layer film 12 (FIG. 1B). The mask film 15 is a film for forming a hard mask which is used when etching the upper layer film 12 as an etching-target film. A material of the mask film 15 will be described in detail later. Subsequently, a resist film 16 is formed on the mask film 15 (FIG. 1C). Then, the alignment mark 14 is detected in an optical manner from above the resist film 16. The wafer 1 is aligned based on a position thus detected. Thereafter, the resist film 16 is exposed.

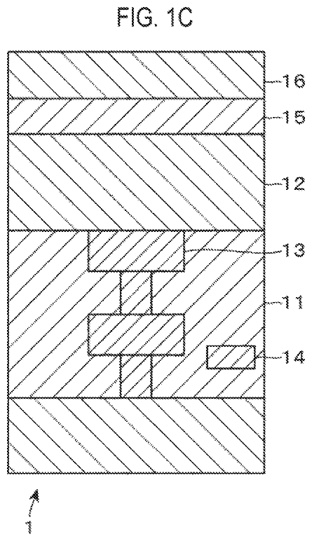

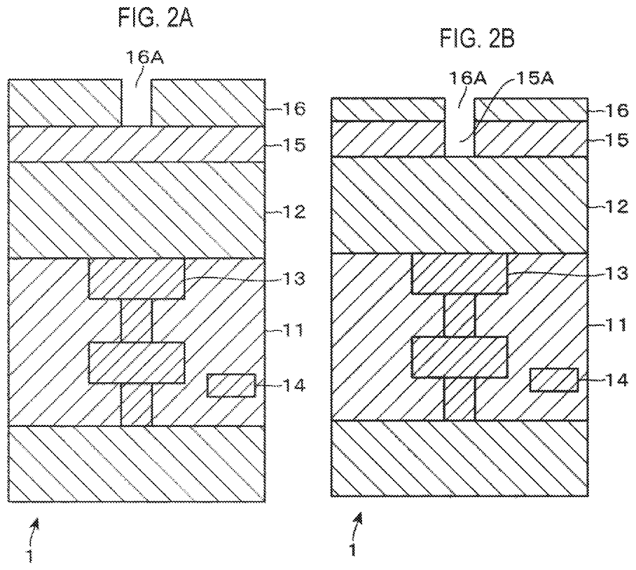

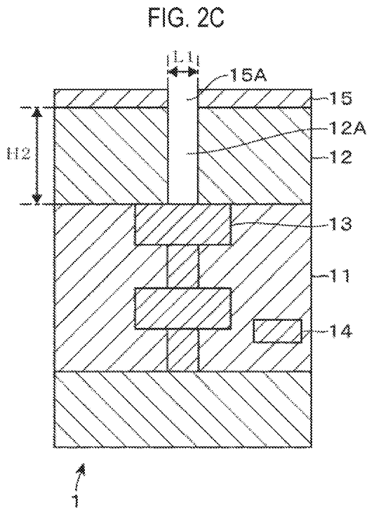

The exposed resist film 16 is developed so as to ⁻form an opening 16A that constitutes a resist pattern. The resist film 16 is configured as a resist mask (FIG. 2A). Thereafter, an etching gas for etching the mask film 15 is supplied to the wafer 1. As a result, an opening 15A constituting a mask pattern is formed in the mask film 15 along the opening 16A. The mask film 15 is configured as a hard mask (FIG. 2B).

Thereafter, an etching gas for etching the upper layer film 12, which contains fluorine such as C₄F₈ (perfluorocyclobutane) gas or the like, is supplied to the wafer 1. As a result, the etching of the upper layer film 12 proceeds using the resist film 16 as a mask when the resist film 16 remains, and the mask film 15 as a mask when the resist film 16 has been removed by etching. Since the wafer 1 has been aligned as described above, the opening 12A is formed in the upper layer film 12 at a predetermined position on the wire 13 through such an etching.

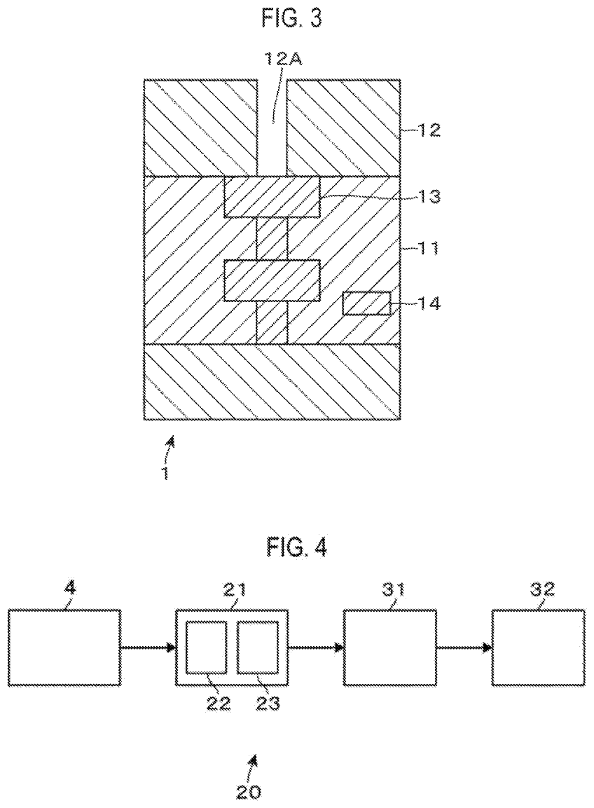

When the etching further proceeds and the wire 13 is exposed in the bottom portion of the opening 12A, the etching stops (FIG. 2C). Thereafter, the wafer 1 is immersed in a chemical solution for selectively removing the mask film 15, so that the mask film 15 which is no longer needed is wet-etched (FIG. 3), In a subsequent process, a wire constituting a semiconductor device is embedded in the opening 12A. As described above, since the opening 12A is formed on the wire 13, the wire embedded in the opening 12A and the wire 13 are electrically connected to each other.

In the case of performing the process of patterning the etching-target film through thy etching as in the above-described process example, conventionally, only the resist mask is used as a mask. However, in this case, with the miniaturization of the wire of the semiconductor device, it is difficult to sufficiently increase an etching selectivity, namely a ratio of an etched amount of the etching-target film with respect to an etched amount of the mask.

As a result, a shape of the processed etching-target film may be deteriorated due to a change in shape of the mask during the etching process, and the mask may be lost during the etching process. Therefore, as in the example described above, by using the hard mask having a higher etching selectivity than that of the resist mask to suppress deformation of the mask during the etching process based the etching gas, it becomes possible to improve the shape of the processed etching-target film.

However, in the semiconductor device manufacturing process, as illustrated in FIGS. 1A to 3, since a previously-processed structure has been formed below the etching-target film and the mask, it is necessary to perform the processing of the etching-target film such that the position thereof is aligned with the previously-processed structure. Therefore, as illustrated in the processing example described above, it is required to optically detect the alignment mark 14 provided below the mask, which is used for the alignment of the wafer 1. The resist film 16 generally has a relatively good light transmittance. Thus, whether or not the optical detection is possible depends on the properties of the hard mask. Accordingly, the hard mask is required to have a high etching selectivity and a high light transmittance. In addition, the light referred to herein is a visible light. In addition, the hard mask becomes unnecessary after the patterning of the etching-target film. Thus, it is also required to remove (peel) the etching-target Film by the wet etching as in the above-described processing example.

Previously, from the viewpoint of the ease of film formation and the ease of peeling before and after the etching process, in addition to a relatively high etching selectivity and a relatively high light transmittance, TiN (titanium nitride) or SiN (silicon nitride) is selected as a material of the hard mask. As the thickness of the hard mask which contains metal or silicon as described above increases, gloss (namely light reflectivity) increases, and the light transmittance decreases. Accordingly, the thickness of the hard mask is limited.

However, in recent years, the wire of the semiconductor device is becoming more miniaturized. Accordingly, the opening of the pattern formed in the etching-target film become smaller, and thus an etching time taken for etching the etching-target film to a required depth tends to be relatively prolonged. In this regard, it is required to configure a hard mask to have a larger etching selectivity while suppressing the thickness thereof to ensure sufficient light transmittance.

Therefore, a compound containing Ru and at least one element selected from Ti, Zr, Hf, V, Nb, Ta, Mo, W and Si, is used as a material of the mask film 15 as a hard mask. Ru is ruthenium, Ti is titanium, Zr is zirconium, Hf is hafnium, V is vanadium, Nb is niobium, Ta is tantalum, Mo is molybdenum, W is tungsten, and Si is silicon. Tests and research have revealed that it is possible to achieve both a good etching selectivity and good light transmittance by configuring a hard mask with the compound described above.

It was confirmed that the compound composed of Ru and at least one element selected from Ti, Zr, Hf, V, Nb, Ta, Mo, W and Si (which is referred to as an “Ru-containing hard mask compound” in some cases) is amorphous. Tests show that the Ru-containing hard mask compound has a relatively high etching selectivity, but the amorphous state is considered to be influential. In addition, as shown in evaluation tests to be described later, when a hard mask is made of Ru alone, the light transmittance is relatively low. However, by adding each of the above-mentioned elements to Ru to form a hard mask, the effect of lowering the light transmittance of Ru in the hard mask is lessened, and thus it is possible to improve the light transmittance. For the sake of avoiding complexity of description, hereinafter, Ti, Zr, Hf, V, Nb, Ta, Mo, W, and Si are sometimes referred to as additive elements added to Ru.

The expression “the mask film 15 is made of Ru” used herein does not mean that the mask film 15 contains Ru as an impurity, but means that the mask film 15 is formed to intentionally contain Ru. Similarly, the expression “the mask film 15 contains at least one element of Ti, Zr, Hf, V, Nb, Ta, Mo, W, and Si” does not mean that the mask film 15 contains the element as an impurity, but means that the mask film 15 is formed to intentionally contain the element. In the Ru-containing hard mask compound, a composition ratio (element component ratio) of Ti, Zr, Hf, V, Nb, Ta, Mo, W, and Si with respect to Ru, is not particularly limited and may be, for example, 1% to 99%.

The above Ru-containing hard mask compound may be nitrided. Such a nitriding process will now be described in detail. Even if the nitriding process is performed, Ru is not bonded to nitrogen and is not nitrided. Meanwhile, each of the additive elements for Ru is bonded with nitrogen to form a nitride. The nitrided element has a higher light transmittance than before nitriding. That is, by using a nitrided Ru-containing hard mask compound, the mask film 15 may have higher light transmittance.

In the above, the case in which the Ru-containing hard mask compound is nitrided was described. However, even in a case where the Ru-containing hard mask compound is oxidized or carbonized, only the additive element for Ru among Ru and the additive element for Ru are oxidized or carbonized as in the case of the nitriding. As a result, the additive element for Ru may have the improved light transmittance and, ultimately, the light transmittance of the mask film 15 may be improved. The mask film 15 may be configured in a practical usage such that, for example, when the front surface of the mask film 15 is radiated with a visible light having a wavelength of 180 nm to 800 nm, in a direction perpendicular to the front surface, the transmittance of light of each wavelength is 10% to 60%.

Meanwhile, since the mask film 15 as a hard mask contains at least Ru as a metal, as a film thickness H1 of the mask film 15 illustrated in FIG. 1B increases, metallic gloss appears as described above and the light transmittance may be decreased. The film thickness H1 may be set to 10 nm or less, as will be described in the evaluation tests to be described later. In addition, when the film thickness H1 is too small, the shape of the opening 15A may become an abnormal shape called a bowing shape, which has poor sidewall verticality. To address this problem, the film thickness H1 may be set to 5 nm or more.

In addition, an opening diameter L1 at an upper end of the opening 12A illustrated in FIG. 2C may be 40 nm or less. A ratio of the opening diameter L1 to a height H2 in the opening 12A, which is an aspect ratio, may be 2 or more. In the case where the opening 12A is formed by etching, the etching time is prolonged as described above. Therefore, it is particularly effective to form the mask film 15 using the Ru-containing hard mask compound.

As shown in the evaluation tests to be described later, by forming the Ru-containing hard mask compound using a compound containing Ru and W among the additive elements for Ru, namely an alloy of Ru and W, it is possible to increase the relative etching selectivity. In addition, the alloy of Ru and W is nitrided, which makes it possible to further increase the etching selectivity. Since only W of Ru and W is nitrided as described above, the compound thus nitrided is an alloy of Ru and WN (tungsten nitride), which is in an amorphous state as described above. It has been confirmed that the arrangement of the elements has higher disorder. A compound obtained by nitriding the alloy of Ru and W is expressed as RuWN. Hereinafter, even in a case where a compound other than RuWN constituting the mask film 15 is described, the compound is expressed in the same manner as the RuWN. That is, Ru and an element selected from the additive elements for Ru are expressed in a side-by-side manner. N is added to show the case where a selected element is nitrided, and N is not added to show the case where the selected element is not nitrided.

Next, a processing system 20 illustrated in FIG. 4 will be described. The processing system 20 includes, for example, a film forming apparatus 4, a resist pattern forming apparatus 21, an etching apparatus 31, and a wet etching apparatus 32 so as to perform a series of processes described with reference to FIGS. 1A to 3. The wafer 1 accommodated in a transfer container is processed while being transferred between the apparatuses in the above order.

In this example, the film forming apparatus 4 forms an RuWN film as the mask film 15 by a physical vapor deposition (PVD) as described above Ti reference to FIG. 1B. An exemplary configuration of the film forming apparatus 4 will be described in detail later. The resist pattern forming apparatus 21 includes a coating/developing apparatus 22 and an exposure apparatus 23. The coating/developing apparatus 22 is configured to perform, through a liquid process, the formation of the resist film 16 as described with reference to FIG. 1C and the formation of the opening 16A obtained by the development as described with reference to FIG. 2A, respectively. The exposure apparatus 23 is configured to perform the exposure of the resist film 16 before the development.

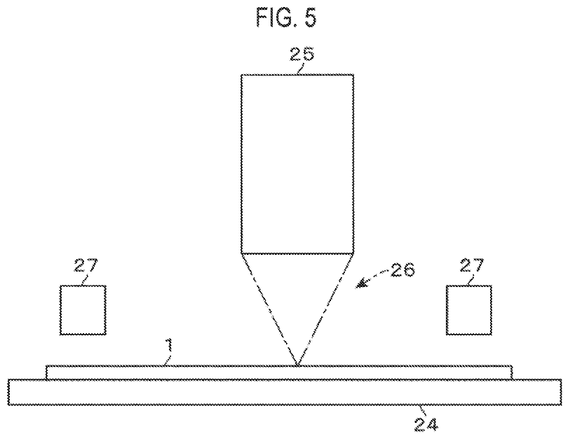

The alignment of the wafer 1 at the time of exposure described above will be described. FIG. 5 is a schematic view of the exposure apparatus 23. The exposure apparatus 23 includes a stage 24 on which the wafer 1 is placed, and an exposure part 25 provided above the stage 24. The stage 24 is configured to be movable and rotatable forwards, backwards, leftwards, and rightwards. The exposure part 25 is configured to irradiate the wafer 1 with an exposure beam 26 through a photomask. In FIG. 5, reference numeral 27 denotes a camera configured to image a front surface of the wafer 1. The alignment mark 14 is detected by such an imaging. The stage 24 moves based on the detected alignment mark 14 such that the wafer 1 is positioned at a predetermined position with respect to the exposure part 25. After the water 1 is aligned in this way, the exposure is performed.

The etching apparatus 31 includes a vacuum container that stores the wafer 1 and forms a vacuum atmosphere therein, and a gas supply part such as a shower head that supplies an etching gas into the vacuum container. Then, as described with reference to FIGS. 2B and 2C, in etching apparatus 31, the opening 15A is formed in the mask film 15, and the opening 12A is formed in the upper layer film 12. The wet etching apparatus 32 includes a tank configured to store a wet etching solution. The wafer 1 is immersed in the wet etching solution so that the mask film 15 is removed as described with reference to FIG. 3.

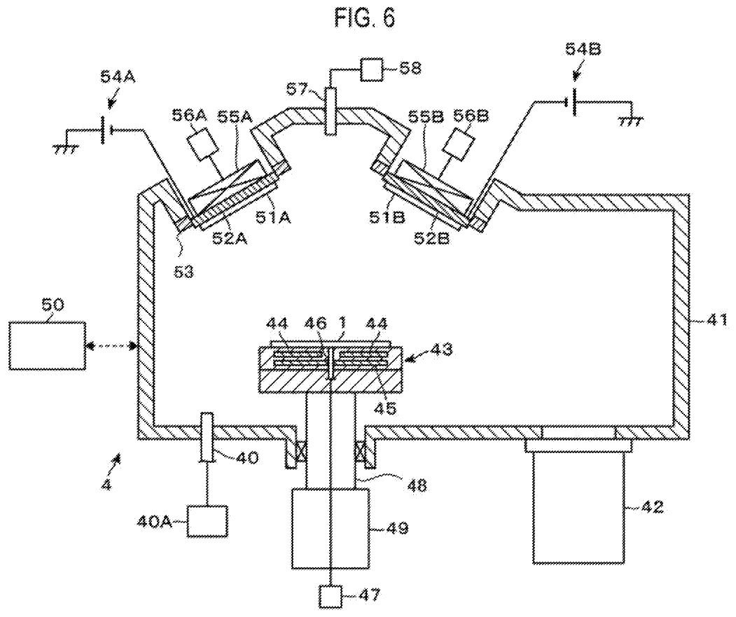

Next, an exemplary configuration of the film forming apparatus 4 for forming the mask film 15 will be described with reference to FIG. 6, In FIG. 6, reference numeral 41 denotes a vacuum container, which is made of ground metal. In FIG. 6, reference numeral 42 denotes an exhaust mechanism configured to exhaust the interior of the vacuum vessel 41 to form a vacuum atmosphere having a desired pressure. In FIG. 6, reference numeral 43 denotes an electrostatic chuck configured to attract the wafer 1, and reference numeral 44 denotes electrodes for wafer attraction, which constitute the electrostatic chuck 43. In FIG. 6, reference numeral 45 denotes a heater configured to heat the wafer 1 placed on the electrostatic chuck 43, and reference numeral 46 denotes a gas supply hole opened in a front surface of the electrostatic chuck 43. The gas supply hole 46 supplies an inert gas supplied from an inert gas source 47 to a rear surface of the wafer 1 as a heat transfer gas for transferring the heat of the electrostatic chuck 43 to the wafer 1.

In FIG. 6, reference numeral 48 denotes a support column that supports the electrostatic chuck 43, and penetrates a bottom portion of the vacuum container 41 and is connected to a drive mechanism 49 at a lower end thereof. By the drive mechanism 49, the electrostatic chuck 43 and the wafer 1 attractively held by the electrostatic chuck 43 rotate around the respective central axes. In addition, a gas supply part 40 is provided in the bottom portion of the vacuum container 41. The gas supply part 40 is connected to an N₂ (nitrogen) gas supply mechanism 40A via a gas flow path.

In a ceiling portion of the vacuum container 41, targets 51A and 51B are respectively provided below plate-shaped electrodes 52A and 52B, and are connected to the respective plate-shaped electrodes 52A and 52B. The targets 51A and 51B are composed of Ru and W, respectively. In FIG. 6, reference numerals 53 denote insulating members, which insulate the electrodes 52A and 52B from the vacuum container 41. DC power supplies 54A and 54B are connected to the respective electrodes 52A and 52B. In FIG. 6, reference numerals 55A and 55B denote magnets provided outside the vacuum container 41. The magnets 55A and 55B move above the respective electrodes 52A and 52B along upper surfaces of the respective electrodes 52A and 52B by the respective magnet driving parts 56A and 56B. A gas supply part 57 is provided in the ceiling portion of the vacuum container 41. The gas supply part 57 is connected to an inert gas supply mechanism 58 via a gas flow path.

In FIG. 6, reference numeral 50 denotes a controller equipped with a computer, which includes a program. According to the program, control signals are outputted from the controller 50 to each part of the film forming apparatus 4 to control the operation of each part. The controller 50 controls the formation of the mask film 15 on the wafer 1, which will be described later. The above program is stored in a storage medium such as a compact disk, a hard disk, a DVD or the like, and is installed on the controller 50.

The processing of the wafer 1 in the film forming apparatus 4 will be described. When a N₂ gas is supplied from the gas supply part 40 and an inert gas is supplied from the gas supply part 57, voltages are applied to the respective targets 51A and 51B from the respective DC power supplies 54A and 54B via the respective electrodes 52A and 52B, and the magnets 55A and 55B are moved. As a result, the inert gas is excited and is formed into a plasma. Positive ions in the plasma collide with each other so that Ru and W respectively constituting the targets 51A and 51B are sputtered and an alloy film of Ru and W is formed on the wafer 1. At this time, the N₂ gas is also formed into a plasma so that the alloy film is nitrided to form the mask film 15 as RuWN.

While in the above, the exemplary configuration of the film forming apparatus 4 in the case of forming RuWN as the mask film 15 has been described, films of other compounds may be formed as the mask film 15 by appropriately selecting the materials constituting the targets 51A and 51B. In the case where the mask film 15 is oxidized or carbonized, an oxygen gas or a gas of a carbon compound such as methane may be supplied from the gas supply part 40 instead of the N₂ gas. In the case where the nitriding, oxidation, and carbonization of the mask film 15 are not performed, the supply of the gases from the gas supply part 40 may be omitted.

According to the present embodiment, by forming the mask film 15 using the Ru-containing hard mask compound, the mask film 15 can have a high light transmittance. Accordingly, the optical detection of the alignment mark 14 is possible, thus preventing the occurrence of a problem in the alignment of the water 1 during the exposure. The mask film 15 has a high etching selectivity. That is, the etching of the mask film 15 is suppressed during the etching of the upper layer film 12. Therefore, even if the opening 12A, which is a pattern formed in the upper layer film 12, is fine, it is possible to etch the opening 12A to a desired depth. Therefore, it is possible to miniaturize the opening 12A and a wire embedded in the opening 12A. In addition, Patent Documents 1 and 2 disclose the technologies for manufacturing a photomask, which are differs in configuration and application from the technology of the present disclosure.

The Ru-containing hard mask compound constituting the mask film 15 may contain two or more elements among Ti, Zr, Hf, V, Nb, Ta, Mo, W, and Si described above. In this case, for example, the film forming apparatus 4 described above may additionally include each set of a target, an electrode, a DC power supply, and a magnet driving part to perform the film forming process. In addition, the mask film 15 is not limited to being formed on the wafer 1 by PVD, but may be formed by, for example, a chemical vapor deposition (CVD). However, in the case where the film formation is performed using the film forming apparatus 4 as described above, it is possible to adjust the distribution of plasma and to adjust the sputtered amount of each of the targets 51A and 51B by adjusting the powers supplied from the DC power supplies 54A and 54B. This makes it possible to adjust the composition ratio of Ru in the Ru-containing hard mask compound and the additive element for Ru. That is, it is advantageous that the composition ratio can be easily adjusted.

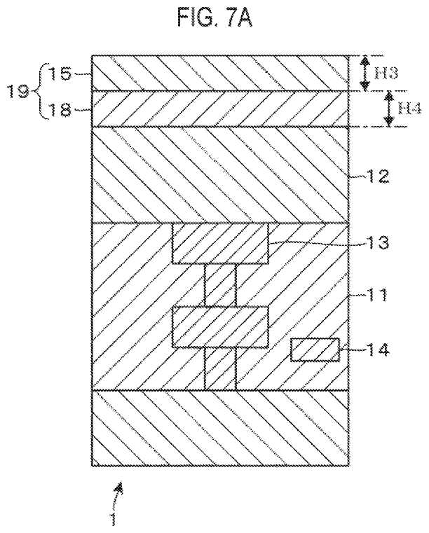

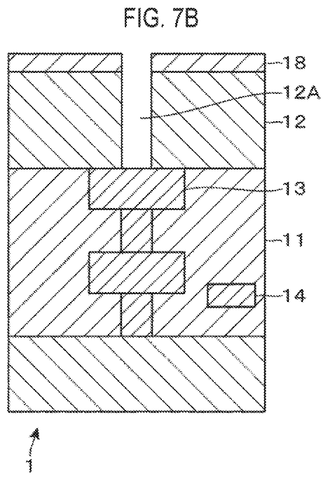

As illustrated in FIG. 7A, a hard mask may be constituted with a laminated film 19 including the mask film 15 made of the Ru-containing hard mask compound and a lower mask film 18 formed under the mask film 15 and not containing Ru. In this case, the mask film 15 corresponds to a first film, and the lower mask film 18 corresponds to a. second film. The lower mask film 18 is made of, for example, TiN or SiN. The expression “the lower mask film 18 does not contain Ru” means that the lower mask film does not contain Ru as a component of the film, but does not mean that Ru is not contained as an impurity. The lower mask film 18 may be formed by PVD or CVD like the mask film 15.

FIG. 7B illustrates a state in which an opening 12A is formed in the upper layer film 12 by performing a process in the procedure described with reference to FIGS. 1A to 3 after forming the laminated film 19. in the etching of the upper layer film 12, since the mask film 15 has a high etching selectivity as described above, the removal of the mask film 15 is suppressed. Even if the mask film 15 is removed, it is possible to continue the etching owing to the lower mask film 18. In addition, each of TiN and SiN has a relatively high light transmittance even if the thickness thereof is relatively large. Therefore, in the case of forming the hard mask with the laminated film 19, it is possible to prevent the hard mask from being removed during etching by making the thickness of the hard mask relatively large while ensuring high light transmittance.

Tests show that a laminated film composed of a TiN film having a thickness of 15 nm and a Ru film having a thickness of 5 nm and formed on the TiN film has good light transmittance. As described above, the Ru-containing hard mask compound exhibits better light transmittance than Ru alone. Accordingly, as an example, by setting a thickness H3 of the mask film 15 to 5 nm or less and a thickness H4 of the lower mask film 18 to 15 nm or less, the laminated film 19 may have good light transmittance.

In a case where the mask film 15 made of an Ru-containing hard mask compound is formed on the lower side and the lower mask film 18 made of TiN or SiN is formed on the upper side, the lower mask film 18 is quickly removed during etching and thus the time taken for removing entire laminated film 19 may be relatively shortened. In view of the foregoing, as described above, the mask film 15 made of an Ru-containing hard mask compound is formed on the upper side, and the lower mask film 18 made of TiN or SiN is formed on the lower side.

In the example described above, the upper layer film 12 as an etching-target film is made of SiO₂, but is not limited to SiO₂ and may be made of, for example, SiN (silicon nitride). When the etching-target film is made of SiN, the lower mask film 18, which is the hard mask described with reference to FIG. 7A, may be made of a material other than SiN. In addition, the optical detection of the alignment mark 14 is not limited to be performed by imaging the wafer 1 as described above. For example, the alignment mark 14 may be configured such that the amounts of reflected lights, which are obtained when the alignment mark 14 is irradiated with light from the side of the front surface of the wafer 1 and when the outside of the alignment mark 14 is irradiated with light from the side of the front surface of the wafer 1, are different from each other. In this case, a light radiation part for locally irradiating the front surface of the wafer 1 with light and a light reception element for receiving a reflected light reflected off the front surface are moved relative to the wafer 1. The alignment mark 14 may be detected based on the amount of reflected light, which is received by the light reception element.

It should be noted that the embodiments disclosed herein are exemplary in all respects and are not restrictive. The above-described embodiments may be omitted, replaced or modified in various forms without departing from the scope and spirit of the appended claims.

### (Evaluation Test)

Next, the evaluation tests performed in relation to the embodiments described above will be described.

### Evaluation Test 1

In Evaluation Test 1, etching was performed by supplying a mixed gas of a C₄F₈ gas and a N₂ gas to each substrate on which different films (referred to as “test films”) are formed. Materials of each test film are TiN, RuW, RuWN, RuHf, and RuHfN. Then, a SiO₂ film was etched under the same conditions and the same processing time as the etching of each test film. For each test film, a ratio of an etched amount of the SiO₂ film to an etched amount of the test film was calculated as an etching selectivity with respect to the SiO₂ film.

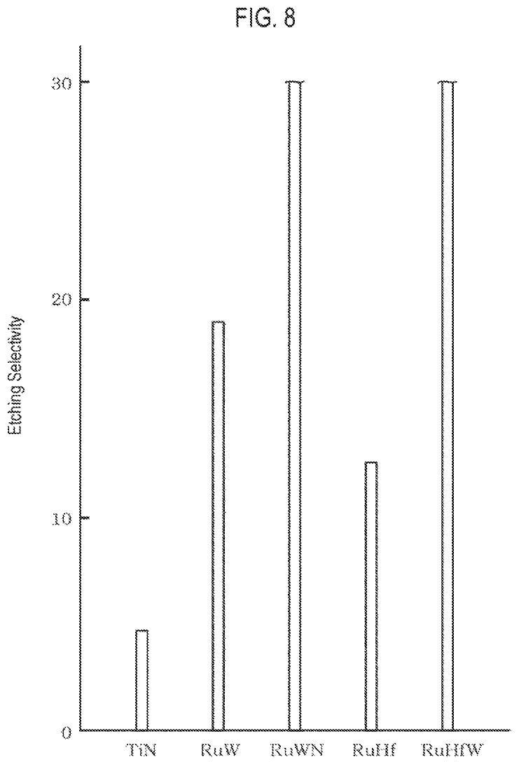

The results of Evaluation Test 1 are shown in a bar graph of FIG. 8, in which the vertical axis of the graph represents the etching selectivity. The etching selectivity of the TiN film was 4.7, the etching selectivity of the RuW film was 19, the etching selectivity of the RuWN film was 30 or more, the etching selectivity of the RuHf film was 12.8, and the etching selectivity of the RuHfN film was 30 or more. Although the TiN film is relatively widely used as a hard mask, as described above, it has difficulty in coping with the miniaturization of pattern. It is practical that the etching selectivity is set to be about twice or more than the etching selectivity of the TiN film, for example, about 10 or greater. Accordingly, it was confirmed from Evaluation Test 1 that the RuW film, the RuWN film, the RuHf film, and the RuHfN film have sufficient etching selectivities in a practical usage. In addition, the etching selectivity of the RuWN film is higher than that of the RuW film, and the etching selectivity of the RuHfN film is higher than that of the RuHf film. That is, it can be seen that the etching selectivity can be increased by nitriding the above Ru-containing hard mask compound.

### Evaluation Test 2

In Evaluation Test 2, a mixed gas of a C₄F₈ gas and a N₂ gas was supplied to a substrate having a SiO₂ film formed thereon, and the SiO₂ film was etched by 120 nm. In addition, a WN film, a RuHfN film, and a RuWN film, which were test films formed on the substrate, were etched for the same time period under the same conditions as the etching of the SiO₂ film. The etched amounts were measured, and the etching selectivities with respect to the SiO₂ film were calculated as in Evaluation Test 1.

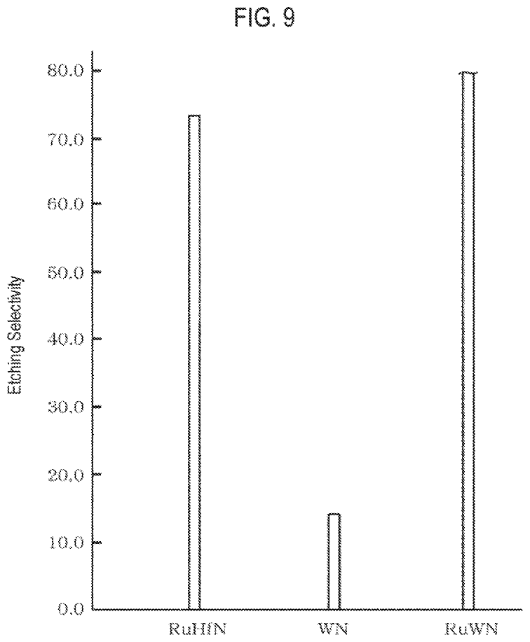

The results of Evaluation Test 2 are shown in a bar graph of FIG. 9, in which the vertical axis of the graph represents the etching selectivity. The etched amount of the WN film was 8.7 nm, the etched amount of the RuHfN film was 1.6 nm, and the etched amount of the RuWN film was 0 nm. Accordingly, the etching selectivity of the WN film was 14, the etching selectivity of the RuHfN film was 74, and the etching selectivity of the RuWN film was 100 or more. Thus, from Evaluation Test 2, it was confirmed that the films of the nitrides of the alloys containing Ru manifest a relatively high etching selectivity, and that in particular, the etching selectivity of the RuWN film was high.

### Evaluation Test 3

In Evaluation Test 3, as in Evaluation Tests 1 and 2, a mixed gas of a C₄F₈ gas and a N₂ gas was supplied as an etching gas to a substrate having test films formed thereon, and the etching selectivity of each test film with respect to the SiO₂ film W was calculated. A RuW film, a RuWN film, and a Ru film were used as the test films, respectively. It was examined whether or not the RuW film, RuWN film, and Ru film were removed from the substrate when the substrate was immersed in a wet etching solution made of a specific compound.

The etching selectivities of the RuW film, the RuWN film, and the Ru film were 19, 30 or more, and 21.5, respectively. Accordingly, all of the etching selectivities were relatively high. The Ru film was not removed by wet etching, but the RuW film and RuWN film were removed. Accordingly, it was confirmed that the RuW film and the RuWN film satisfy requirements necessary for use as a hard mask.

### Evaluation Test 4

In Evaluation Test 4, a WN film and a RuWN film were formed on a plurality of glass plates, respectively. The film thickness of each of the WN film and the RuWN film was changed for each glass plate, and each of the WN film and the RuWN film was formed to have a film thickness of 10 nm or 20 nm. In addition, each glass plate, which was subjected to such a film formation, was placed on a substrate on which a character is printed such that the character is covered by the glass plate. Examination was performed to check whether or not the character could be recognized visually.

Regarding the RuWN film, it was possible to confirm the character when the thickness thereof was 10 nm, but it was difficult to recognize the character when the thickness thereof was 20 nm. Regarding the WN film, when the thickness thereof was 10 nm, it was possible to recognize the character, but when the thickness thereof was 20 nm, it was difficult to recognize the character. In addition, when the RuWN film and the WN film have the same thickness, it was slightly easier to recognize the character in the WN film rather than the RuWN film, but there was no significant difference in ease of recognition.

From the results of Evaluation Test 4, it was confirmed that, by forming the RuWN film to have a thickness of 10 nm or less, it is possible to secure sufficient light transmittance. The RuWN film was confirmed to have a high etching selectivity in Evaluation Tests 1 to 3, and was confirmed to be removable by wet etching in Evaluation Test 3. Furthermore, the RuWN film was confirmed to have light transmittance in Evaluation Test 4. That is, from the results of Evaluation Tests 1 to 4, it can be seen that that the RuWN film is suitable as a hard mask.

### Evaluation Test 5

In Evaluation Test 5, a test similar to Evaluation Test 4 was performed. However, the combinations of the types and thicknesses of films formed on the glass plates were different from those in Evaluation Test 4. In Evaluation Test 5, a TiN film having a thickness of 20 nm, and Ru film having a thickness of 20 nm, a Ru film having a thickness of 10 nm, and a TiRuN film haying a thickness of 20 nm were formed on respective glass plates. The TiRuN film is obtained by forming two types of films having different composition ratios of Ti and Ru. A film having a relatively small composition ratio of Ru is referred to as a first TiRuN film, and a film having a relatively large composition ratio of Ru is referred to as a second TiRuN

Regarding the ease of character recognition, namely the light transmittance, the TiN film having a thickness of 20 nm>the Ru film having a thickness of 10 nm=the first TiRuN film having a thickness of 20 nm>the second TiRuN film having a thickness of 20 nm>the Ru film having a thickness of 20 nm. However, the test results show that it is desirable to have light transmittance higher than that of the first TiRuN film having a thickness of 20 nm. From the results of Evaluation Test 5 and the results of Evaluation Test 4, it is considered that the film thickness of the Ru-containing hard mask compound may be set to 10 nm or less from the viewpoint of having sufficient light transmittance.

According to the present disclosure in some embodiments, in forming a pattern by etching an etching-target film formed on a substrate for manufacturing a semiconductor device, it is possible to achieve the miniaturization of the pattern without causing a problem in alignment of the substrate for the etching.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A hard mask formed on a substrate for manufacturing a semiconductor device, the hard mask comprising:
a film made of a compound which is composed of Ru and an element selected from Ti, Zr, Hf, V, Nb, Ta, Mo, W, and Si.

2. The hard mask of claim 1, wherein the film has a thickness of 10 nm or less.

3. The hard mask of claim 2, wherein the compound is a nitrided, oxidized or carbonized compound.

4. The hard mask of claim 3, wherein the compound is amorphous.

5. The hard mask of claim 4, wherein, assuming that the film is a first film, the hard mask further comprises the first film and a second film not containing Ru and laminated under the first film.

6. The hard mask of claim 5, wherein the second film is TiN or SiN.

7. The hard mask of claim 6, wherein the compound contains W.

8. The hard mask of claim 1, wherein the compound is a nitrided, oxidized or carbonized compound.

9. The hard mask of claim 1, wherein the compound is amorphous.

10. The hard mask of claim 1, wherein, assuming that the film is a first film, the hard mask further comprises the first film and a second film not containing Ru and laminated under the first film.

11. The hard mask of claim 1, wherein the compound contains W.

12. A method of manufacturing a semiconductor device, the method comprising:
forming a hard mask formation-purpose mask on an etching-target film formed on a substrate for manufacturing the semiconductor device, the hard mask formation-purpose film being made of a compound which is composed of Ru and an element selected from Ti, Zr, Hf, V, Nb, Ta, Mo, W, and Si;
forming a pattern on the hard mask formation-purpose film to form a hard mask; and
etching the etching-target film through the hard mask.

13. The method of claim 12, further comprising:
forming a resist film on the hard mask formation-purpose film, that occurs after the forming a hard mask formation-purpose film;
detecting a mark located below the hard mask formation-purpose film in the substrate in an optical manner; and
forming a resist pattern by exposing the resist film based on a position of the detected mark, and foaming the pattern on the hard mask formation-purpose film through the resist pattern.
